(19) United States
(12) Patent Application Publication
(10) Pub. No.: US 2011/0220492 A1
(43) Pub. Date: Sep. 15, 2011

(54) SURFACE PLANARIZATION METHOD

(75) Inventor: Hidetoshi HANAOKA, Nirasaki-shi (JP)

(73) Assignee: TOKYO ELECTRON LIMITED, Tokyo (JP)

(21) Appl. No.: 13/041,485

(22) Filed: Mar. 7, 2011

Related U.S. Application Data
(60) Provisional application No. 61/318,634, filed on Mar. 29, 2010.

(30) Foreign Application Priority Data
Mar. 10, 2010 (JP) 2010-052956

(51) Int. Cl. C23C 14/34

(52) U.S. Cl. 204/192.37

(57) ABSTRACT

Disclosed is a surface planarization method capable of planarizing the surface of a substrate while maintaining the film thickness of a polysilicon layer. A wafer formed with a polysilicon layer on the surface thereof is loaded on a susceptor of a chamber of a substrate processing apparatus, the pressure in the chamber is set to any one of 100 mTorr or more and 800 mTorr or less, and the flow ratio of argon gas in a mixed gas of oxygen gas and argon gas is set to any one of 50% or more and 95% or less, plasma is generated by exciting the mixed gas with a high-frequency power having a frequency set to any one of 13 MHz or more and 100 MHz or less, and the surface of the wafer is sputtered by positive ions of oxygen or argon in the generated plasma.

### CROSS-REFERENCE TO RELATED APPLICATIONS

This application is based on and claims priority from Japanese Patent Application No. 2010-052956, filed on Mar. 10, 2010, with the Japanese Patent Office, the disclosure of which is incorporated herein in its entirety by reference. Also, this application claims the benefit of U.S. Provisional Application No. 61/318634 filed on Mar. 29, 2010, with the United States Patent and Trademark Office, which is herein incorporated by reference in its entirety.

### TECHNICAL FIELD

The present disclosure relates to a surface planarization method of a substrate having a polysilicon layer on the surface thereof.

### BACKGROUND

Although a wafer serving as a substrate on which a semiconductor device is manufactured has, in particular, a high purity silicon layer (e.g., a polysilicon layer) on a surface thereof, polysilicon layer 40 routinely has minute irregularities as shown in FIG. 4A. As the semiconductor device further miniaturized, the irregularities of polysilicon layer 40 may deteriorate the performance of a gate electrode of a transistor, and thus, a technology has been developed that removes the irregularities of the polysilicon layer, that is, a technology that planarizes the surface of the wafer before forming the gate electrode of the transistor has been developed.

As the planarization technology, as shown in FIG. 4B, for example, a method of etching the surface of the wafer using an oxygen plasma has been known. In this method, plasma is generated from a mixture of oxygen gas and fluorine contained gas, and polysilicon layer 40 is sputtered by positive ions 41 of oxygen or fluorine in the plasma. See, for example, Japanese Patent Application Laid-Open No. 2001-160551. In this case, positive ions 41 preferentially etch a convex portion of polysilicon layer 40, and as a result, polysilicon layer 40 is planarized.

However, in the above-mentioned method, since the pressure in a processing chamber where plasma is generated is approximately several mTorr order and relatively close to vacuum, a relatively thick sheath 42 having, e.g., a thickness of approximately 1 cm is generated along the surface of a wafer. Therefore, since positive ions 41 passing through sheath 42 are sufficiently accelerated to sputter a polysilicon layer 40, an etching amount of polysilicon layer 40 increases, and as a result, the film thickness of polysilicon layer 40 decreases as shown in FIG. 4C. Further, in this method, since an oxygen plasma is present, an oxide layer is formed on the surface of polysilicon layer 40 during the process of planarization. However, the oxide layer is also etched by the sputtering of positive ions 41, such that the oxide layer does not contribute to maintaining the film thickness of polysilicon layer 40.

### SUMMARY

The present disclosure has been made in an effort to provide a surface planarization method capable of planarizing the surface of a substrate while maintaining a film thickness of a polysilicon layer on the surface.

An exemplary embodiment of the present disclosure provides a surface planarization method including: introducing a mixed gas including oxygen gas and argon gas into a processing chamber where a substrate formed with a polysilicon layer on the surface thereof is positioned; generating plasma by exciting the mixed gas through application of high-frequency power to an inner part of the processing chamber; and sputtering the surface of the substrate by positive ions in the plasma, wherein a pressure in the processing chamber is 100 mTorr or more and 800 mTorr or less (13.3 Pa or more and 106.6 Pa or less), a flow ratio of argon gas in the mixed gas is 50% or more and 95% or less, and a frequency of the high-frequency power is 13 MHz or more and 100 MHz or less.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram schematically showing a configuration of a substrate processing apparatus executing a surface planarization method according to a first exemplary embodiment of the present disclosure.

FIG. 2 is a process diagram showing a surface planarization method according to the first exemplary embodiment of the present disclosure.

FIG. 3 is a process diagram showing a surface planarization method according to a second exemplary embodiment of the present disclosure.

FIG. 4 is a process diagram showing a surface planarization method in the related art.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

An exemplary embodiment of the present disclosure provides a surface planarization method including: introducing a mixed gas including oxygen gas and argon gas into a processing chamber where a substrate formed with a polysilicon layer on the surface thereof is positioned; generating plasma by exciting the mixed gas through application of high-frequency power to an inner part of the processing chamber; and sputtering the surface of the substrate by positive ions in the plasma. In particular, the pressure in the processing chamber is 100 mTorr or more and 800 mTorr or less (13.3 Pa or more and 106.6 Pa or less), a flow ratio of argon gas in the mixed gas is 50% or more and 95% or less, and a frequency of the high-frequency power is 13 MHz or more and 100 MHz or less.

The pressure in the processing chamber may be 400 mTorr or more and 800 mTorr or less (53.3 Pa or more and 106.6 Pa or less), and may be 400 mTorr or more and 600 mTorr or less (53.3 Pa or more and 80.0 Pa or less). Also, the flow ratio of argon gas in the mixed gas may be 70% or more and 95% or less. Moreover, the frequency of the high-frequency power may be 27 MHz or more and 60 MHz or less, the output of the high-frequency power may be 500 W or more, and the output of the high-frequency power may be 800 W or more.

Another exemplary embodiment of the present disclosure provides a surface planarization method including: introducing a mixed gas including oxygen gas and helium gas into a processing chamber where a substrate formed with a polysilicon layer on the surface thereof is positioned; generating plasma by exciting the mixed gas through application of high-frequency power to an inner part of the processing chamber; and sputtering the surface of the substrate by positive ions in the plasma. In particular, the pressure in the processing chamber is 100 mTorr or more and 800 mTorr or less, a flow ratio of helium gas in the mixed gas is 50% or more and 95% or less, and a frequency of the high-frequency power is 13 MHz or more and 100 MHz or less.

The pressure in the processing chamber may be 400 mTorr or more and 800 mTorr or less, and may be 400 mTorr or more and 600 mTorr or less. Also, the flow ratio of helium gas in the mixed gas may be 70% or more and 95% or less. In particular, the frequency of the high-frequency power may be 27 MHz or more and 60 MHz or less, an output of the high-frequency power may be 500 W or more, and the output of the high-frequency power may be 800 W or more.

According to a first aspect of the present disclosure, since a pressure in a processing chamber is 100 mTorr or more, a sheath generated on a surface of a substrate in the processing chamber is relatively thin, and positive ions of oxygen or argon passing through the sheath are not particularly accelerated, and as a result, a polysilicon layer can be prevented from being over-etched. In addition, since the pressure in the processing chamber is 800 mTorr or less, positive ions of oxygen or argon are guaranteed to sputter the polysilicon layer by ensuring the generation of the sheath, and as a result, the convex portion of the polysilicon layer can surely be removed.

Further, since the flow ratio of argon gas in mixed gas is 50% or more, mixed gas is facilitated to become plasma to generate positive ions of oxygen or argon at a predetermined amount or more, and as a result, the convex portion of the polysilicon layer can surely be removed. In addition, since a flow ratio of argon gas in mixed gas is 95% or less, plasma of oxygen can be generated at a predetermined amount or more, and as a result, the surface of the polysilicon layer can be surely oxidized.

Furthermore, since the frequency of high-frequency power is 13 MHz or more, DC bias voltage generated based on applied high-frequency power is prevented from being increased to prevent positive ions of oxygen or argon from flowing into a substrate more than a necessary amount, and as a result, the polysilicon layer can be prevented from being over-etched. In addition, since the frequency of the high-frequency power is 100 MHz or less, the positive ions of oxygen or argon are guaranteed to sputter the polysilicon layer ensuring the generation of the DC bias voltage, and as a result, the convex portion of the polysilicon layer can surely be removed.

As a result, while the convex portion of the polysilicon layer is sufficiently removed, the polysilicon layer is not overetched, and an oxide layer is formed on the surface of the polysilicon layer. Therefore, the film thickness of the polysilicon layer is maintained to planarize the surface of the substrate.

According to a second aspect of the present disclosure, since the pressure in a processing chamber is 100 mTorr or more and 800 mTorr or less, a sheath generated on a surface of a substrate in the processing chamber is relatively thin and positive ions of oxygen passing through the sheath are not particularly accelerated, and as a result, a polysilicon layer can be prevented from being overetched. In addition, since the pressure in the processing chamber is 800 mTorr or less, positive ions of oxygen are guaranteed to sputter the polysilicon layer ensuring the generation of the sheath, and as a result, the convex portion of the polysilicon layer can surely be removed.

Further, since a flow ratio of helium gas in mixed gas is 50% or more, plasma is activated to increase the energy of plasma, and as a result, the convex portion of the polysilicon layer can surely be removed. In addition, since the flow ratio of helium gas in mixed gas is 95% or less, plasma of oxygen can be generated at a predetermined amount or more, and as a result, the surface of the polysilicon layer can be surely oxidized.

Furthermore, since the frequency of high-frequency power is 13 MHz or more, DC bias voltage generated based on applied high-frequency power is prevented from being increased to prevent positive ions of oxygen from flowing into a substrate more than a necessary amount, and as a result, the polysilicon layer can be prevented from being overetched. In particular, since the frequency of the high-frequency power is 100 MHz or less, the positive ions of oxygen are guaranteed to sputter the polysilicon layer by ensuring the generation of the DC bias voltage, and as a result, the convex portion of the polysilicon layer can surely be removed.

As a result, while the convex portion of the polysilicon layer is sufficiently removed, the polysilicon layer is not overetched, and an oxide layer is formed on the surface of the polysilicon layer. Therefore, the film thickness of the polysilicon layer is maintained to planarize the surface of the substrate.

Hereinafter, exemplary embodiments of the present disclosure will be described with reference to the accompanying drawings.

First, a substrate processing apparatus executing a surface planarization method according to a first exemplary embodiment of the present disclosure will be described.

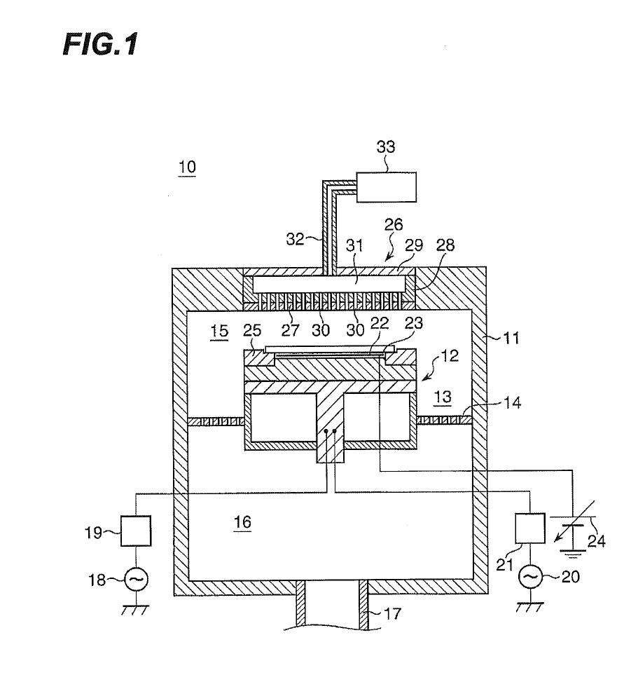

FIG. 1 is a diagram schematically showing the configuration of a substrate processing apparatus executing a surface planarization method according to a first exemplary embodiment of the present disclosure. The substrate processing apparatus performs a plasma etching of a wafer for semiconductor devices (hereinafter, simply referred to as ‘a wafer’) serving as a substrate.

In FIG. 1, a substrate processing apparatus 10 includes, for example, a chamber 11 housing a wafer W having a diameter of 300 mm, and a cylindrical susceptor 12 on which a semiconductor device wafer W is loaded is disposed in chamber 11. In substrate processing apparatus 10, lateral exhaust passages 13 are formed by inner walls of chamber 11 and side portions of susceptor 12. An exhaust plate 14 is disposed in the middle of lateral exhaust passage 13.

Exhaust plate 14 is a plate-like member having a plurality of through-holes and serves as a partition plate partitioning an inner part of chamber 11 into an upper part and a lower part. Plasma is generated in an upper part 15 (hereinafter, referred to as ‘a processing chamber’) of the inner part of chamber 11 partitioned by exhaust plate 14 as described below. Further, an exhaust duct 17 that discharges gas contained in chamber 11 is connected to a lower part 16 (hereinafter, referred to as ‘an exhaust chamber (a manifold)’) of the lower part of chamber 11. Exhaust plate 14 captures or reflects plasma generated in processing chamber 15 to prevent the plasma from being leaked to manifold 16.

A turbo molecular pump (TMP) and a dry pump (DP) (both not shown) are connected to exhaust duct 17 and the pumps depressurize the inner part of chamber 11 to a vacuum state. A pressure in chamber 11 is controlled by an automatic performance control (APC) valve (not shown).

A first high-frequency power supply 18 is connected to susceptor 12 in chamber 11 through a first matching device 19 and a second high-frequency power supply 20 is connected to susceptor 12 in chamber 11 through a second matching device 21. First high-frequency power supply 18 applies ion injecting high-frequency power of a relatively low frequency, for example, 2 MHz to susceptor 12 and second high-frequency power supply 20 applies plasma generating high-frequency power of a relatively high frequency, for example, 60 MHz to susceptor 12. As a result, susceptor 12 serves as an electrode. Further, first matching unit 19 and second matching unit 21 reduce reflection of the high-frequency power from susceptor 12 to maximize application efficiency of the high-frequency power to susceptor 12.

An upper part of susceptor 12 has a shape in which a cylinder having a small diameter protrudes upwardly along a concentric axis from a front end of a cylinder having a large diameter, and a step is formed in the upper part to surround the cylinder having the small diameter. An electrostatic chuck 23 made of ceramics having an electrostatic electrode plate 22 therein is disposed at a front end of the cylinder having the small diameter. A DC power supply 24 is connected to electrostatic electrode plate 22 and when plus DC voltage is applied to electrostatic electrode plate 22, a minus potential is generated on a surface (hereinafter, referred to as ‘a rear surface’) at the side of electrostatic chuck 23 in wafer W, such that a potential difference is generated between electrostatic electrode plate 22 and the rear surface of wafer W. Accordingly, wafer W is adsorbed and maintained to electrostatic chuck 23 by Coulomb force or Johnson-Rahbek force caused by the potential difference.

Further, a focus ring 25 is loaded on the step formed in the upper part of susceptor 12 to surround wafer W adsorbed and maintained to electrostatic chuck 23, in the upper part of susceptor 12. Focus ring is made of silicon (Si). That is, since focus ring 25 is made of a semiconducting material, a distribution area of plasma is expanded to focus ring 25 as well as onto wafer W to maintain plasma density on the peripheral edge of wafer W to be the same as plasma density on the center of wafer W. As a result, uniformity of plasma etching performed on the entire surface of wafer W is ensured.

A shower head 26 is disposed on a ceiling of chamber 11 to oppose susceptor 12. Shower head 26 includes an upper electrode plate 27, a cooling plate 28 removably suspending and supporting upper electrode plate 27, and a cover 29 covering cooling plate 28. Upper electrode plate 27 is formed of a disk-like member having a plurality of gas holes 30 penetrating in a thickness direction and made of silicon which is the semiconducting material. Further, a buffer chamber 31 is installed in cooling plate 28, a processing gas introduction duct 32 is connected to buffer chamber 31, and processing gas introduction duct 32 is connected to a processing gas supplying device 33.

Processing gas supplying device 33, for example, appropriately adjusts the flow ratio of oxygen gas and argon gas to generate a mixed gas, and then, introduces the mixed gas into processing chamber 15 through buffer chamber 31 and gas holes 30.

In substrate processing apparatus 10, processing gas introduced into processing chamber 15 is excited by the plasma generating high-frequency power applied to an inner part of processing chamber 15 from second high-frequency power supply 20 through susceptor 12 to become plasma. Ions in the plasma are injected toward wafer W by the ion injecting high-frequency power applied to susceptor 12 by first high-frequency power supply 18 performing a plasma etching on wafer W.

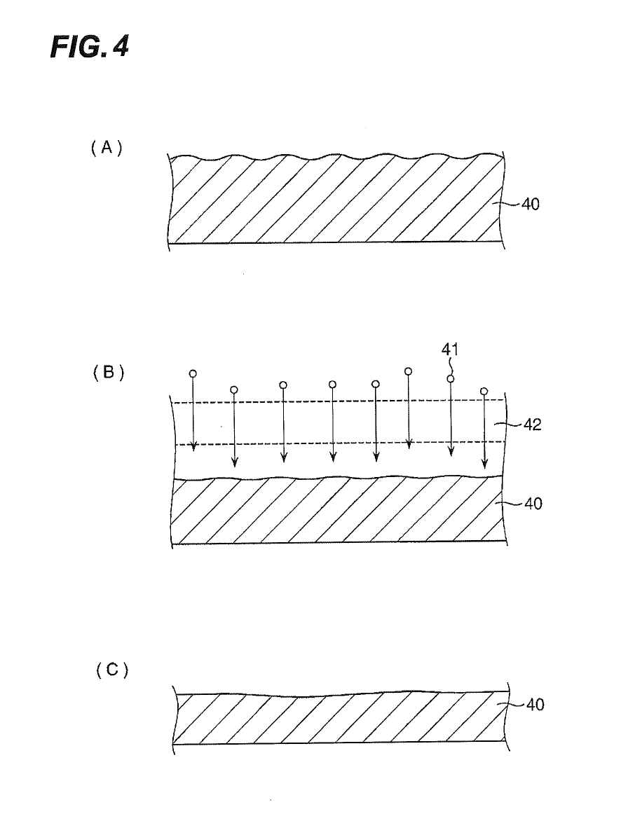

However, in regards to a wafer W having a polysilicon layer 40 on the surface thereof as shown in FIG. 4A, the present inventor has performed various experiments in order to discover a method of planarizing the surface of wafer W while maintaining a film thickness of polysilicon layer 40. As a result, the present inventor has discovered that the surface of wafer W can be planarized while maintaining the film thickness of polysilicon layer 40 when plasma is generated from the mixed gas including oxygen gas and argon gas under a predetermined condition and wafer W is processed by using the plasma.

Specifically, it has been found out that when the pressure in chamber 11 is set to 100 mTorr or more and 800 mTorr or less, for example, 400 mTorr or more and 800 mTorr or less, or, 400 mTorr or more and 600 mTorr or less; the flow ratio of argon gas in the mixed gas is set to 50% or more and 95% or less, for example, 70% or more and 95% or less; the frequency of the plasma generating high-frequency power is set to 13 MHz or more and 100 MHz or less, for example, 27 MHz or more and 60 MHz or less without applying the ion injecting high-frequency power; and the output of the plasma generating high-frequency power is set to 500 W or more and 2000 W or less, for example, 800 W or more and 1700 W or less, the surface of wafer W can be planarized while maintaining the film thickness of polysilicon layer 40.

When plasma is generated from the mixed gas including oxygen gas and argon gas under the above-described conditions, it has been found out that the following assumption may be made regarding the planarization effect while maintaining the film thickness of polysilicon layer 40.

First, when the pressure in chamber 11 is excessively low, a sheath generated on the surface of wafer W becomes thick and positive ions of oxygen or argon passing through the sheath is accelerated to be more than sufficient. Accordingly, an etching amount of polysilicon layer 40 is increased by sputtering with the positive ions of oxygen or argon, such that polysilicon layer 40 becomes excessively thin.

However, when the pressure in chamber 11 is 100 mTorr or more, the sheath becomes relatively thinner and the positive ions of oxygen or argon passing through the sheath are not particularly accelerated, and as a result, it is possible to suppress polysilicon layer 40 from being etched by sputtering with the positive ions of oxygen or argon. In addition, when the pressure in chamber 11 is 400 mTorr or more, the sheath may become thinner, and as a result, it is possible to further suppress polysilicon layer 40 from being etched. In addition, since DC bias voltage Vdc is stabilized at a low value, for example, approximately 50 V, it is possible to suppress the positive ions of oxygen or argon from being injected into polysilicon layer 40, thereby further suppressing polysilicon layer 40 from being etched.

Further, when the pressure in chamber 11 is excessively high, no sheath is generated, and as a result, since the positive ions of oxygen or argon is not accelerated to be more than sufficient, the positive ions of oxygen or argon do not reach polysilicon layer 40. Even though the positive ions reach polysilicon layer 40, the positive ions thereof have not been accelerated, and as a result, polysilicon layer 40 may not be etched.

However, when the pressure in chamber 11 is 800 mTorr or less, it is possible to prevent the sheath from being not generated. As a result, since the positive ions of oxygen or argon may be appropriately accelerated by the sheath, the positive ions of oxygen or argon are prevented from not sputtering the polysilicon layer, thereby preventing polysilicon layer 40 from being not etched.

When the flow ratio of argon gas in the mixed gas is excessively low, the mixed gas is not facilitated to become plasma, and as a result, since the positive ions of oxygen or argon are not particularly generated, polysilicon layer 40 is rarely etched.

However, when the flow ratio of argon gas in the mixed gas is 50% or more, the mixed gas is facilitated to become plasma by presence of argon gas (consequently, electron density in chamber 11 is increased), and as a result, the positive ions of oxygen or argon are sufficiently generated, thereby ensuring the etching of polysilicon layer 40. In addition, when the flow ratio of argon gas in the mixed gas is 70% or more, the mixed gas may be further facilitated to become plasma.

Further, when the flow ratio of argon gas in the mixed gas is excessively high, plasma of oxygen is rarely generated, such that an oxide layer may not be formed on the surface of polysilicon layer 40. However, when the flow ratio of argon gas in the mixed gas is 95% or less, plasma of oxygen may be generated with a predetermined amount or more, and as a result, the oxide layer may be formed on the surface of polysilicon layer 40.

When the ion injecting high-frequency power is not applied and the frequency of the plasma generating high-frequency power is excessively low, self bias voltage (DC bias voltage) generated in susceptor 12 is increased by the high-frequency power and the excessive positive ions of oxygen or argon are injected into wafer W to increase an etching amount of polysilicon layer 40 by sputtering with the positive ions of oxygen or argon, and as a result, polysilicon layer 40 becomes excessively thin.

However, when the frequency of the plasma generating high-frequency power is 13 MHz or more, the DC bias voltage can be prevented from being increased. As a result, excessive positive ions of oxygen or argon are prevented from being injected into wafer W, thereby preventing polysilicon layer 40 from being excessively etched. In addition, when the frequency of the plasma generating high-frequency power is 27 MHz or more, only necessary and sufficient amount of positive ions of oxygen or argon may be injected into wafer W, and as a result, an excessive etching of polysilicon layer 40 may clearly be prevented.

Further, when the frequency of the plasma generating high-frequency power is excessively high, the DC bias voltage is not generated, and as a result, since the positive ions of oxygen or argon are not injected into wafer W, polysilicon layer 40 is rarely etched.

However, when the frequency of the plasma generating high-frequency power is 100 MHz or less, the generation of the DC bias voltage is ensured to inject the positive ions of oxygen or argon into wafer W, and as a result, polysilicon layer 40 is surely etched. In addition, when the frequency of the plasma generating high-frequency power is 60 MHz or less, the generation of the DC bias voltage is ensured.

When the output of the plasma generating high-frequency power is small, the mixed gas is facilitated to become plasma, and as a result, polysilicon layer 40 is rarely etched.

However, when the output of the plasma generating high-frequency power is 500 W or more, the mixed gas is facilitated to become plasma, polysilicon layer 40 is ensured to be etched. In addition, when the output of the plasma generating high-frequency power is 800 W or more, the mixed gas may be further facilitated to become plasma.

Further, when the output of the plasma generating high-frequency power is large, DC bias voltage Vdc is increased and the etching amount of polysilicon layer 40 is increased by sputtering with the positive ions of argon, such that polysilicon layer 40 becomes excessively thin.

However, when the output of the plasma generating high-frequency power is 2000 W or less, DC bias voltage Vdc is prevented from being extremely increased, for example, to be maintained to 140 V or less, thereby preventing polysilicon layer 40 from being excessively etched. When the output of the plasma generating high-frequency power is 1700 W or less, DC bias voltage Vdc may be maintained to 120 V or less.

The present disclosure is based on the above findings.

A surface planarization method according to a first exemplary embodiment of the present disclosure will be described herein below.

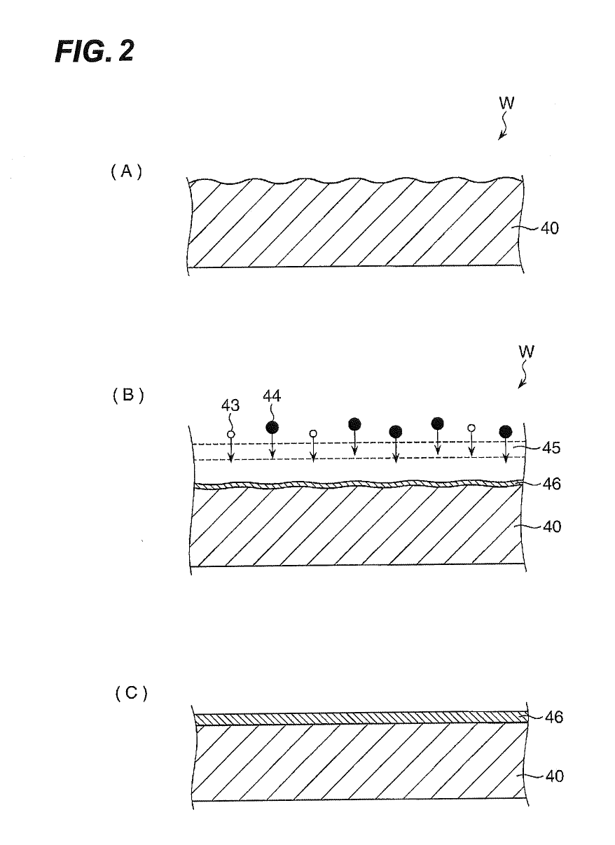

FIG. 2 is a process diagram showing a surface planarization method according to a first exemplary embodiment of the present disclosure.

In FIG. 2, a wafer W having a polysilicon layer 40 on the surface thereof is loaded first on a susceptor 12 in a chamber 11, and wafer W is adsorbed and maintained by an electrostatic chuck 23 (FIG. 2A).

Subsequently, chamber 11 is depressurized by an exhaust duct 17, a pressure in chamber 11 is set to any one of 100 mTorr or more and 800 mTorr or less by using an APC valve, mixed gas of oxygen gas and argon gas is generated by a processing gas supplying device 33, the flow ratio of argon gas in the mixed gas is set to any one of 50% or more and 95% or less, and the mixed gas is introduced into a processing chamber 15 from a shower head 26.

Subsequently, plasma generating high-frequency power is applied to susceptor 12 without applying ion injecting high-frequency power. Herein, a frequency of the plasma generating high-frequency power is set to any one of 13 MHz or more and 100 MHz or less, and an output of the plasma generating high-frequency power is set to any one of 500 W or more and 2000 W or less.

In this case, plasma of oxygen or argon is generated from the mixed gas, and positive ions 43 of oxygen or positive ions 44 of argon in the plasma are injected into a polysilicon layer 40 by DC bias voltage as self bias voltage generated in susceptor 12 or a relatively thin sheath 45 generated on the surface of wafer W. Accordingly, the convex portion of polysilicon layer 40, thereby planarizing polysilicon layer 40 is preferentially etched. Further, plasma of oxygen forms an oxide layer 46 on the surface of polysilicon layer 40 (see FIG. 2B).

Subsequently, after a predetermined time has elapsed, the mixed gas stops to be injected into processing chamber 15, the plasma generating high-frequency power stops to be applied, and the pressure in chamber 11 stops to be controlled, thereby terminating the processing. In this case, the convex portion of polysilicon layer 40 is removed and polysilicon layer 40 is planarized. Further, an oxide layer 46 having a predetermined thickness is formed on the surface of polysilicon layer 40. Therefore, a total value of a thickness of polysilicon layer 40 and a thickness of oxide layer 46 after planarization is substantially the same as that of polysilicon layer 40 before planarization.

By the surface planarization method according to the first exemplary embodiment of the present disclosure, since the pressure in chamber 11 is set to any one of 100 mTorr or more and 800 mTorr or less, the flow ratio of argon gas in the mixed gas of oxygen gas and argon gas introduced into processing chamber 15 is set to any one of 50% or more and 95% or less, the frequency of the plasma generating high-frequency power applied to susceptor 12 is set to any one of 13 MHz or more and 100 MHz or less without applying the ion injecting high-frequency power, and the output of the plasma generating high-frequency power is set to any one of 500 W or more and 2000 W or less, polysilicon layer 40 is not excessively etched while the convex portion of polysilicon layer 40 is sufficiently removed, and oxide layer 46 is formed on polysilicon layer 40. As a result, the surface of wafer W can be planarized while maintaining the film thickness of polysilicon layer 40.

Further, in the surface planarization method according to the first exemplary embodiment of the present disclosure, polysilicon layer 40 may be planarized concurrently with the formation of oxide layer 46 at the same time in one chamber 11 to thereby achieve an efficient processing.

In particular, in the planarization method of the surface according to the first exemplary embodiment of the present disclosure, polysilicon layer 40 corresponding to a ground of a gate can be planarized and oxide layer 46 corresponding to a gate oxide layer can be formed. In addition, since used gas is stable gas such as oxygen gas or argon gas, a reaction product causing unnecessary insulation is not generated. Accordingly, the surface planarization method is suitable to manufacture transistor devices.

Next, a surface planarization method according to a second exemplary embodiment of the present disclosure will be described.

In addition to the surface planarization method according to the first exemplary embodiment as described above, the surface of wafer W may be planarized with another method. For example, plasma may be generated from a mixed gas including oxygen gas and helium gas under a predetermined condition and wafer W is processed by using the plasma. The surface of wafer W may then be planarized while maintaining the film thickness of polysilicon layer 40.

Specifically, the surface of wafer W can be planarized while maintaining the film thickness of polysilicon layer 40 when the pressure in chamber 11 is set to 100 mTorr or more and 800 mTorr or less, for example, 400 mTorr or more and 800 mTorr or less, and for example, 600 mTorr or more and 800 mTorr or less, the flow ratio of helium gas in the mixed gas is set to 50% or more and 95% or less, for example, 70% or more and 95% or less, the frequency of the plasma generating high-frequency power is set to 13 MHz or more and 100 MHz or less, for example, 27 MHz or more and 60 MHz or less without applying the ion injecting high-frequency power, and the output of the plasma generating high-frequency power is set to 500 W or more and 2000 W or less, for example, 800 W or more and 1700 W or less,.

When plasma is generated from the mixed gas including oxygen gas and helium gas under the above-described conditions, it has been found out that the following assumption may be made regarding the planarization effect while maintaining the film thickness of polysilicon layer 40.

The same assumption as in the first exemplary embodiment of the present disclosure will not be omitted. Further, in the second exemplary embodiment, while positive ions of helium are also accelerated by a sheath to sputter polysilicon layer 40, the positive ions are relatively small in molecular weight and therefore, rarely contribute to etching. Accordingly, the movements of the positive ions of helium will not be described in the following assumption.

When the flow ratio of helium gas in the mixed gas is excessively low, energy of plasma cannot be increased (consequently, electron temperature in chamber 11 is not particularly increased), and as a result, polysilicon layer 40 cannot be sputtered by the positive ions of oxygen having high energy. Therefore, polysilicon layer 40 is rarely etched.

However, when the flow ratio of helium gas in the mixed gas is 50% or more, plasma is activated by the presence of helium gas to increase the energy of plasma (consequently, electron density in chamber 11 is increased), and as a result, polysilicon layer 40 can be sputtered by the positive ions of oxygen having high energy. Therefore, polysilicon layer 40 is ensured to be etched. In addition, when the flow ratio of helium gas in the mixed gas is 70% or more, the energy of plasma may be further increased.

The present disclosure is based on the above findings.

Next, a surface planarization method according to a second exemplary embodiment of the present disclosure will be described.

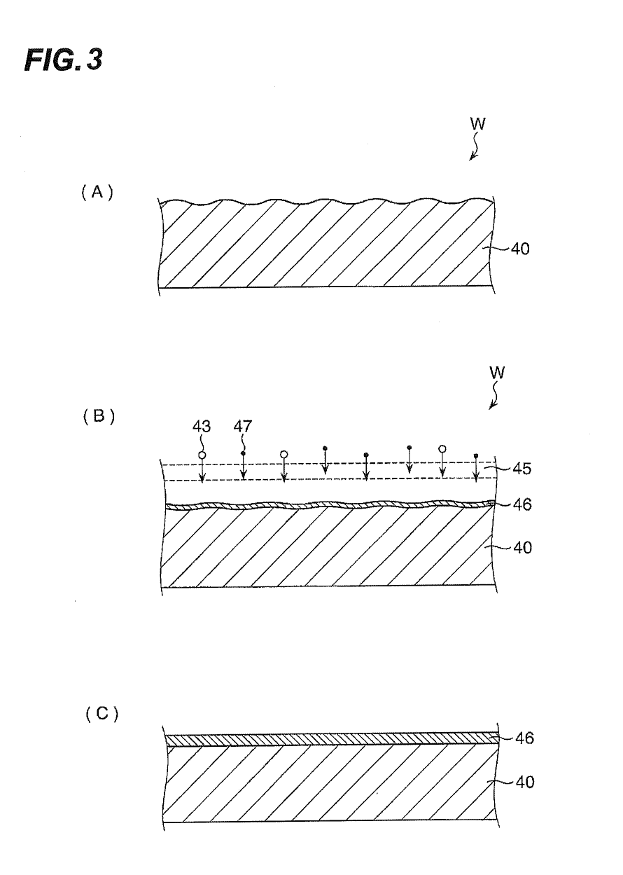

FIG. 3 is a process diagram showing a surface planarization method according to a second exemplary embodiment of the present disclosure.

In FIG. 3, a wafer W having a polysilicon layer 40 on the surface thereof is loaded first on a susceptor 12 in a chamber 11, and adsorbed and maintained by an electrostatic chuck 23 (FIG. 3A).

Subsequently, a series of processes are conducted. For example, chamber 11 is depressurized by an exhaust duct 17, a pressure in chamber 11 is set to any one of 100 mTorr or more and 800 mTorr or less by using an APC valve, mixed gas of oxygen gas and helium gas is generated by a processing gas supplying device 33, a flow ratio of helium gas in the mixed gas is set to any one of 50% or more and 95% or less, and the mixed gas is introduced into a processing chamber 15 from a shower head 26.

Subsequently, plasma generating high-frequency power is applied to susceptor 12 without applying ion injecting high-frequency power. Herein, a frequency of the plasma generating high-frequency power is set to any one of 13 MHz or more and 100 MHz or less, and an output of the plasma generating high-frequency power is set to any one of 500 W or more and 2000 W or less.

In this case, plasma of oxygen or helium is generated from the mixed gas, positive ions 43 of oxygen or positive ions 47 of helium in the plasma are injected into a polysilicon layer 40 by DC bias voltage as self bias voltage generated in susceptor 12 or by a relatively thin sheath 45 generated on the surface of wafer W. In particular, positive ions 43 of oxygen preferentially etch a convex portion of polysilicon layer 40, thereby planarizing polysilicon layer 40. Further, plasma of oxygen forms an oxide layer 46 on the surface of polysilicon layer 40 (see FIG. 3B).

Subsequently, when a predetermined time has elapsed, the mixed gas stops to be introduced into processing chamber 15, the plasma generating high-frequency power stops to be applied, and the pressure in chamber 11 stops to be controlled, thereby terminating the processing. In this case, the convex portion of polysilicon layer 40 is removed to planarize polysilicon layer 40, and the combined thickness of polysilicon layer 40 and oxide layer 46 after the planarization is substantially the same as the thickness of polysilicon layer 40 before planarization.

By the planarization method of the surface according to the second exemplary embodiment of the present disclosure, since the pressure in chamber 11 is set to any one of 100 mTorr or more and 800 mTorr or less, the flow ratio of helium gas in the mixed gas of oxygen gas and helium gas introduced into processing chamber 15 is set to any one of 50% or more and 95% or less, the frequency of the plasma generating high-frequency power applied to susceptor 12 is set to any one of 13 MHz or more and 100 MHz or less without applying the ion injecting high-frequency power, and the output of the plasma generating high-frequency power is set to any one of 500 W or more and 2000 W or less. Accordingly, polysilicon layer 40 is not excessively etched while the convex portion of polysilicon layer 40 is sufficiently removed, and oxide layer 46 is formed on polysilicon layer 40. As a result, the surface of wafer W can be planarized while maintaining the film thickness of polysilicon layer 40.

Further, similar to the surface planarization method of the first exemplary embodiment, polysilicon layer 40 may be planarized concurrently with the formation of oxide layer 46 at the same time in one chamber 11 in the second exemplary embodiment and suitable to manufacture transistor devices as well.

Although the surface planarization method utilized in substrate processing apparatus 10 where the ion injecting high-frequency power and the plasma generating high-frequency power are applied to susceptor 12 has been described in each exemplary embodiment described above, the surface planarization method of the present disclosure may be applied to a substrate processing apparatus where the ion injecting high-frequency power is applied to susceptor 12 and the plasma generating high-frequency power is applied to upper electrode plate 27 of shower head 26.

In this case, when the frequency of the ion injecting high-frequency power is 13 MHz or more, the high-frequency power fluctuates rapidly, and, as a result, since the positive ions cannot follow the fluctuation, the output of the ion injecting high-frequency power may be adjusted so that DC bias voltage Vdc becomes a predetermined value or more, for example, 50 V or more, in order to inject the positive ions into susceptor 12.

Further, when the frequency of the ion injecting high-frequency power is 13 MHz or less, the positive ions can follow the fluctuation of the high-frequency power. As a result, the DC bias voltage does not need to be a predetermined value or more, but the mixed gas should be facilitated to become plasma. As a result, the output of the plasma generating high-frequency power needs to be adjusted so that high-frequency voltage Vpp applied between susceptor 12 and shower head 26 becomes any one of 600 V to 800 V.

The substrate where the substrate processing apparatus performs plasma etching by executing the surface planarization method according to the exemplary embodiments described above is not limited to a semiconductor device wafer, and various substrates may be used, such as, for example, a photomask, a CD substrate, or a printed circuit board used in a flat panel display (FPD) including a liquid crystal display (LCD), etc.

Although the present disclosure has been described by using each exemplary embodiment, the present disclosure is not limited to each exemplary embodiment.

The present disclosure can be also achieved by supplying a storage medium storing a program of software implementing the functions of each of the above-described exemplary embodiments to a computer, etc. and by reading and executing the program stored in the storage medium by a CPU of the computer.

In this case, the program read from the storage medium implements the functions of each of the above-described exemplary embodiments, and the program and the storage medium storing the program constitutes the present disclosure.

In addition, various types of storage medium may be used for supplying the program. For example, RAM, NV-RAM, a floppy (registered trademark) disk, a hard disk, a magneto-optical disk, an optical disk such as a CD-ROM, a CD-R, a CD-RW, DVDs (DVD-ROM, DVD-RAM, DVD-RW, and DVD+RW), etc., a magnetic tape, a non-volatile memory card, other ROMs, etc., that can store the program may be used. Alternatively, the program may be downloaded from other computers or database (not shown) connected to the Internet, commercial networks, or local area networks, and may thus be supplied to the computer.

In addition, the functions of each of the above-described exemplary embodiments may be implemented by executing the computer-readable program, and further, an operating system (OS) operated on the CPU performs some or all of the actual processes based on the instruction of the program. Also, the functions of each of the above-mentioned exemplary embodiments may be implemented according to the processes.

Further, the program read from the storage medium is recorded in a memory included in a function extension board inserted into the computer or a function extension unit connected to the computer, and then, the CPU installed in the function extension board or the function extension unit executes some or all of the actual processes based on the instruction of the program, and the functions of each exemplary embodiment as described above may be also implemented.

The type of the above program may be an object code, a program executed by an interpreter, script data supplied to the OS, and the like.

### EXEMPLARY EMBODIMENT

Next, exemplary embodiments of the present disclosure will be described. First Exemplary Embodiment

A wafer W having a polysilicon layer 40 having a thickness of 492 nm on the surface thereof is prepared and the surface planarization method of FIG. 2 is performed. In this case, the pressure in chamber 11 is set to 400 mTorr, the flow ratio of argon gas in mixed gas is set to 92% (the flow rate of oxygen gas: 100 sccm and the flow rate of argon gas: 1100 sccm), the frequency of plasma generating high-frequency power is set to 40 MHz, and the output of the high-frequency power is set to 800 W.

The followings are verified after the surface planarization method of FIG. 2 is performed on wafer W. Polysilicon layer 40 is planarized at the center of wafer W, the combined thickness of polysilicon layer 40 and oxide layer 46 is 502 nm (the thickness of oxide layer 46 is 35 nm), polysilicon layer 40 is planarized even on the periphery of wafer W, and the combined thickness of polysilicon layer 40 and oxide layer 46 is 490 nm (the thickness of oxide layer 46 is 38 nm). It is also verified that the electron density in chamber 11 increases while performing the surface planarization method of FIG. 2.

### SECOND EXEMPLARY EMBODIMENT

A wafer W having a polysilicon layer 40 having a thickness of 492 nm on the surface thereof is prepared and the surface planarization method of FIG. 3 is performed. In this case, the pressure in chamber 11 is set to 400 mTorr, the flow ratio of helium gas in mixed gas is set to 92% (the flow rate of oxygen gas: 100 sccm and the flow rate of helium gas: 1100 sccm), the frequency of plasma generating high-frequency power is set to 40 MHz, and the output of the high-frequency power is set to 500 W.

The followings are verified after the surface planarization method of FIG. 3 is performed on wafer W. Polysilicon layer 40 is planarized at the center of wafer W, the combined thickness of polysilicon layer 40 and oxide layer 46 is 492 nm (the thickness of oxide layer 46 is 34 nm), polysilicon layer 40 is planarized even on the periphery of wafer W, and the total thickness of polysilicon layer 40 and oxide layer 46 is 478 nm (the thickness of oxide layer 46 is 46 nm). It is also verified that electron density in chamber 11 increases while performing the surface planarization method of FIG. 3.

That is, it is found out that the surface of wafer W can be planarized while maintaining the film thickness of polysilicon layer 40 on the surface of wafer W by the surface planarization method of FIG. 2 or 3.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A surface planarization method comprising:
introducing a mixed gas including oxygen gas and argon gas into a processing chamber where a substrate formed with a polysilicon layer on the surface thereof is positioned;
generating plasma by exciting the mixed gas through application of a high-frequency power to an inner part of the processing chamber; and
sputtering the surface of the substrate by positive ions in the plasma,
wherein a pressure in the processing chamber is 100 mTorr or more and 800 mTorr or less (13.3 Pa or more and 106.6 Pa or less), a flow ratio of argon gas in the mixed gas is 50% or more and 95% or less, and a frequency of the high-frequency power is 13 MHz or more and 100 MHz or less.

2. The method of claim 1, wherein the pressure in the processing chamber is 400 mTorr or more and 800 mTorr or less (53.3 Pa or more and 106.6 Pa or less).

3. The method of claim 2, wherein the pressure in the processing chamber is 400 mTorr or more and 600 mTorr or less (53.3 Pa or more and 80.0 Pa or less).

4. The method of claim 1, wherein the flow ratio of argon gas in the mixed gas is 70% or more and 95% or less.

5. The method of claim 1, wherein the frequency of the high-frequency power is 27 MHz or more and 60 MHz or less.

6. The method of claim 1, wherein an output of the high-frequency power is 500 W or more.

7. The method of claim 6, wherein the output of the high-frequency power is 800 W or more.

8. A surface planarization method comprising:
introducing a mixed gas including oxygen gas and helium gas into a processing chamber where a substrate formed with a polysilicon layer on the surface thereof is positioned;
generating plasma by exciting the mixed gas through application of high-frequency power to an inner part of the processing chamber; and
sputtering the surface of the substrate by positive ions in the plasma,
wherein a pressure in the processing chamber is 100 mTorr or more and 800 mTorr or less, a flow ratio of helium gas in the mixed gas is 50% or more and 95% or less, and a frequency of the high-frequency power is 13 MHz or more and 100 MHz or less.

9. The method of claim 8, wherein the pressure in the processing chamber is 400 mTorr or more and 800 mTorr or less.

10. The method of claim 9, wherein the pressure in the processing chamber is 400 mTorr or more and 600 mTorr or less.

11. The method of claim 8, wherein the flow ratio of helium gas in the mixed gas is 70% or more and 95% or less.

12. The method of claim 8, wherein the frequency of the high-frequency power is 27 MHz or more and 60 MHz or less.

13. The method of claim 8, wherein an output of the high-frequency power is 500 W or more.

14. The method of claim 13, wherein the output of the high-frequency power is 800 W or more.
